(19) United States
(12) Patent Application Publication
(10) Pub. No.: US 2015/0021709 A1
(43) Pub. Date: Jan. 22, 2015

(54) STRUCTURES AND METHODS INTEGRATING DIFFERENT FIN DEVICE ARCHITECTURES

(71) Applicant: GLOBALFOUNDRIES Inc., Grand Cayman (KY)

(72) Inventors: Ajey P. JACOB, Albany, NY (US); Murat Kerem AKARVARDAR, Saratoga Springs, NY (US); Michael John HARGROVE, Clinton Corners, NY (US)

(21) Appl. No.: 13/945,379

(22) Filed: Jul. 18, 2013

(51) Int. Cl. H01L 27/12; H01L 21/8234; H01L 29/06; H01L 21/762

(52) U.S. Cl. CPC H01L 27/1211; H01L 21/76281; H01L 21/823481; H01L 21/823431; H01L 29/0649
USPC 257/401; 438/413

(57) ABSTRACT

Semiconductor structures and fabrication methods are provided integrating different fin device architectures on a common wafer, for instance, within a common functional device area of the wafer. The method includes: facilitating fabricating multiple fin device architectures within a common functional device wafer area by: providing a wafer with at least one fin disposed over a substrate, the fin including an isolation layer; modifying the fin(s) in a first region of the fin(s), while protecting the fin in a second region of the fin(s); and proceeding with forming one or more fin devices of a first architectural type in the first region and one or more fin devices of a second architectural type in the second region. The first architectural type and the second architectural type are different fin device architectures, such as different fin device isolation architectures, different fin type transistor architectures, or different fin-type devices or structures.

### FIELD OF THE INVENTION

The present invention relates to semiconductor devices such as fin devices, and methods of facilitating fabricating semiconductor devices, and more particularly to structures and methods of integrating different fin device architectures and isolation schemes within, for instance, a common functional device wafer area.

### BACKGROUND OF THE INVENTION

Fin field-effect transistor (FinFET) devices are currently being developed to replace conventional planar metal oxide semiconductor field-effect transistors (MOSFETs) in advanced complementary metal oxide semiconductor (CMOS) technology due to their improved short-channel effect immunity and higher on-current to off-current ratio (Iₒₙ/I_{off}). As is known, the term “fin” refers to a vertical structure within or upon which are formed, for instance, one or more FinFETs or other fin devices, such as passive devices, including capacitors, diodes, etc.

Further enhancements in fin device structures and fabrication methods therefor continue to be pursued for enhanced performance and commercial advantage.

### BRIEF SUMMARY

The shortcomings of the prior art are overcome, and additional advantages are provided through the provision, in one aspect, of a method which includes facilitating fabricating multiple fin device architectures. The facilitating fabricating includes: providing a wafer with at least one fin disposed over a substrate, the at least one fin including an isolation layer; modifying the at least one fin in a first fin region, while protecting the at least one fin in a second fin region thereof; and proceeding with forming at least one fin device of a first architectural type in the first fin region and at least one fin device of a second architectural type in the second fin region, wherein the first architectural type and the second architectural type are different fin device architectures.

In another aspect, a semiconductor structure is presented herein which includes a semiconductor substrate, at least one fin, and at least one fin device of a first architectural type in a first fin region of the at least one fin and at least one fin device of a second architectural type in a second fin region of the at least one fin. The at least one fin resides over the semiconductor substrate and includes an active layer, and an isolation layer between the active layer and the semiconductor substrate. The first architectural type and the second architectural type of the fin devices are different fin device architectures.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1A depicts an intermediate structure in a semiconductor structure fabrication process, in accordance with one or more aspects of the present invention;

FIG. 1B depicts the intermediate structure of FIG. 1A after processing to add an active layer, over the sacrificial layer, in accordance with one or more aspects of the present invention;

FIG. 1C depicts the intermediate structure of FIG. 1B after processing to create multiple fins from the multi-layer structure, in accordance with one or more aspects of the present invention;

FIG. 1D depicts the intermediate structure of FIG. 1C after provision of a conformal oxide over the structure, in accordance with one or more aspects of the present invention;

FIG. 1E depicts the intermediate structure of FIG. 1D after an oxidation of the remaining portions of the sacrificial layer has been performed, in accordance with one or more aspects of the present invention;

FIG. 1F depicts the intermediate structure of FIG. 1D after a partial oxidation of the sacrificial layer portions has been performed, in accordance with one or more aspects of the present invention;

FIG. 1G depicts the intermediate structure of FIG. 1E after recessing the conformal oxide to at least partially reveal the active layer of the fins, in accordance with one or more aspects of the present invention;

FIG. 1H depicts the intermediate structure of FIG. 1G after gate structure formation, in accordance with one or more aspects of the present invention;

FIG. 1I depicts the intermediate structure of FIG. 1H rotated 90° and showing a single-fin with multiple gate structures disposed thereon, in accordance with one or more aspects of the present invention;

FIG. 1J is a plan view of the intermediate structure of FIGS. 1H & 1I, depicting multiple regions of a wafer, for instance, within a common functional device wafer area, in accordance with one or more aspects of the present invention;

FIG. 1K is a plan view of the intermediate structure of FIG. 1J, wherein a first region of the structure remains exposed and a second region has been protected by a protective layer, in accordance with one or more aspects of the present invention;

FIG. 1L is a cross-sectional elevational view of the intermediate of structure of FIG. 1K, taken along line 1L-1L thereof, in accordance with one or more aspects of the present invention;

FIG. 1M is a cross-sectional elevational view of the intermediate structure of FIG. 1K, taken along line 1M-1M thereof, in accordance with one or more aspects of the present invention;

FIG. 1N depicts the intermediate structure of FIG. 1M after formation of multiple recesses in the first region thereof extending through the illustrated fin into the substrate, in accordance with one or more aspects of the present invention;

FIG. 1O depicts the intermediate structure of FIG. 1N after removal of the protective layer from the second region thereof, in accordance with one or more aspects of the present invention;

FIG. 1P depicts the intermediate structure of FIG. 1O after provision of a material filling the fin recesses, and illustrating an elevational cross-section through the fin on the left (i.e., the first region) and an elevational cross-section between fins on the right (i.e., the second region), in accordance with one or more aspects of the present invention;

FIG. 2 depicts one embodiment of a process for facilitating fabricating multiple fin device architectures, for instance, within a common functional device wafer area, in accordance with one or more aspects of the present invention; and

FIG. 3 depicts a wafer with a common functional device wafer area including a first region with at least one fin device of a first architectural type, and a second region with at least one fin device of a second architectural type, in accordance with one or more aspects of the present invention.

### DETAILED DESCRIPTION

Aspects of the present invention and certain features, advantages, and details thereof, are explained more fully below with reference to the non-limiting examples illustrated in the accompanying drawings. Descriptions of well-known materials, fabrication tools, processing techniques, etc, are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

The present disclosure provides, in part, methods and structures integrating multiple different fin device architectures, for instance, within a common functional device wafer area. Different fin device architectures and/or fin isolation approaches may be desired for different applications, and the ability to facilitate fabrication of multiple different fin device architectures on a common wafer without significant additional cost is believed significant.

As examples of how different fabrication schemes may be used to create different fin device architectures, low-leakage fin device architectures may be achieved through a fin isolation scheme, while fin architectures with higher on-current may be achieved through the use of embedded stress elements such as embedded sources and drains extending through, for instance, a fin isolation layer into the substrate. A challenge arises when the characteristics of more than one fin device architecture are desired within, for instance, a common functional device wafer area, since conventional fin fabrication methods would only yield a single fin device architecture within a given functional device wafer area.

Generally stated, provided herein, in one aspect, is a method for facilitating fabricating multiple fin device architectures. The facilitating fabricating includes: providing a wafer with at least one fin disposed over a substrate the at least one fin, including an isolation layer; modifying the at least one fin in a first fin region of the at least one fin, while protecting the at least one fin in a second fin region thereof; and proceeding with forming at least one fin device of a first architectural type in the first fin region of the at least one fin, and at least one fin device of a second architectural type in the second fin region of the at least one fin, wherein the first architectural type and the second architectural type are different fin device architectures. For example, the at least one fin device of the first architectural type may include at least one fin transistor of the first architectural type, and the at least one fin device of the second architectural type may include at least one fin transistor of the second architectural type, wherein the first architectural type transistor and second architectural type transistor are different types of transistors. As one example, the first architectural type transistor may include at least one embedded stress element extending through the isolation layer into the substrate, and the at least one fin transistor of the second architectural type in the second fin region may lack any embedded stress element extending through the fin into the substrate. For instance, the at least one fin transistor of the second architectural type in the second fin region may be an isolated-type fin transistor.

In one embodiment, the modifying of the first fin region of the at least one fin may include forming at least one fin recess in one fin of the at least one fin within the first fin region, while protecting the one fin in the second fin region. The at least one fin recess may expose the substrate beneath the fin, and the wafer may include multiple gate structures disposed over the one fin. In such a case, the modifying may include forming multiple fin recesses in the one fin in the first fin region of the at least one fin, each fin recess being disposed adjacent to one or more gate structures of the multiple gate structures in the first fin region of the at least one fin. In one implementation, the substrate may be a semiconductor substrate, and the proceeding may include epitaxially growing a semiconductor material, at least in part, from the semiconductor substrate through the at least one fin recess in the one fin. The epitaxially growing may also provide the semiconductor material, at least partially, over the one fin in the second fin region. By way of example, the epitaxially-grown semiconductor material may include one of silicon germanium, or silicon carbon, or silicon germanium doped with carbon, depending, for instance, on the type of transistor being formed.

In one implementation, providing the wafer may include providing a multi-layer structure which includes: the substrate; an isolation layer disposed over the substrate and an active semiconductor layer disposed over the isolation layer; and thereafter, removing at least a portion of the multi-layer structure to create the at least one fin. The at least one fin includes a portion of the active layer disposed above a portion of the isolation layer. In one embodiment, the substrate may be a semiconductor substrate, and providing the multi-layer structure may include: providing an intermediate semiconductor structure which includes the semiconductor substrate, a sacrificial layer over the substrate (which includes an oxidizable material), and the active semiconductor layer disposed over the sacrificial layer; etching the intermediate semiconductor structure to create the at least one fin, each fin of the at least one fin including a portion of the active layer, a portion of the sacrificial layer, and a portion of the semiconductor substrate; and selectively oxidizing the sacrificial layer of the at least one fin, while maintaining structural stability therefor, wherein the oxidized, sacrificial layer provides the isolation layer. In one implementation, providing the intermediate semiconductor structure includes epitaxially growing the sacrificial layer. The selectively oxidizing may include providing a conformal oxide about the at least one fin, and annealing the at least one fin and conformal oxide to locally oxidize the sacrificial layer in the at least one fin.

An enhanced semiconductor structure is also provided herein which includes a semiconductor substrate, at least one fin residing on the semiconductor substrate, and at least one fin device of a first architectural type in the first fin region of the at least one fin and at least one fin device of a second architectural type in the second fin region of the at least one fin, wherein the first architectural type and the second architectural type are different fin device architectures. In this implementation, the at least one fin includes an active layer, and an isolation layer between the active layer and the semiconductor substrate. As noted, the at least one fin device of the first architectural type may include at least one fin transistor of the first architectural type, and the at least one fin transistor of the first architectural type may include at least one embedded stress element extending through the isolation layer of the at least one fin, into the semiconductor substrate. The at least one fin device of the second architectural type may include at least one fin transistor of the second architectural type, and the at least one fin transistor of the second architectural type may be, for instance, an isolated-type fin transistor. In one implementation, the first architectural type and the second architectural type utilize or include different fin device isolation architectures relative to the isolation layer of the at least one fin within, for instance, a common functional device wafer area. In another example, the at least one fin device of the first architectural type and the at least one fin device of the second architectural type, may reside in different functional device areas of the wafer.

Reference is made below to the drawings, which are not drawn to scale for ease of understanding, wherein the same reference numbers used throughout different figures designate the same or similar components.

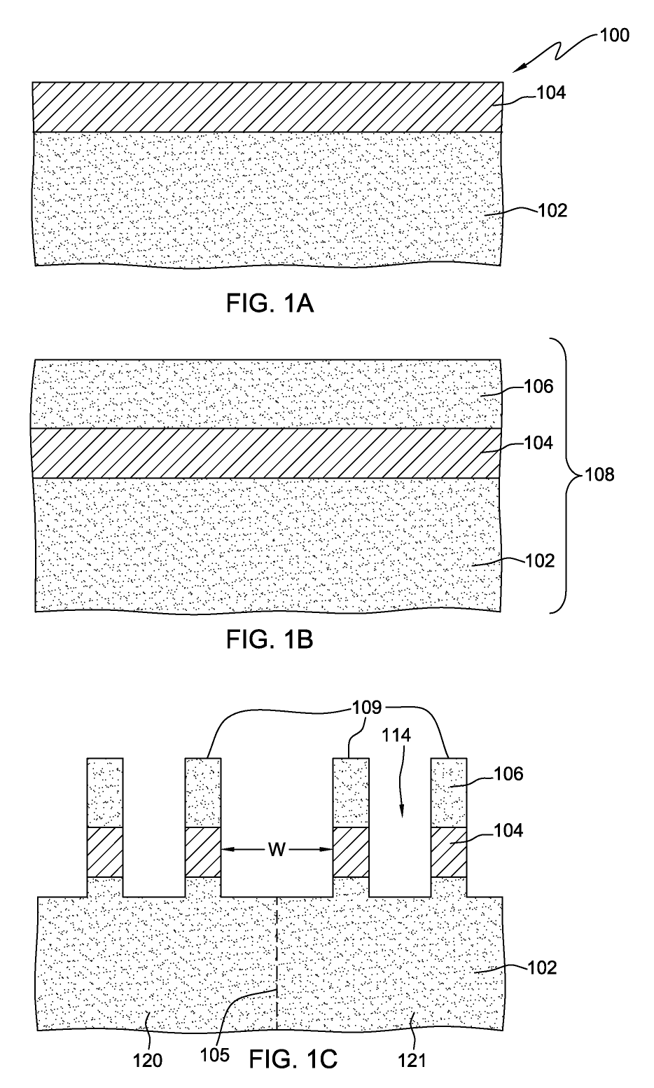

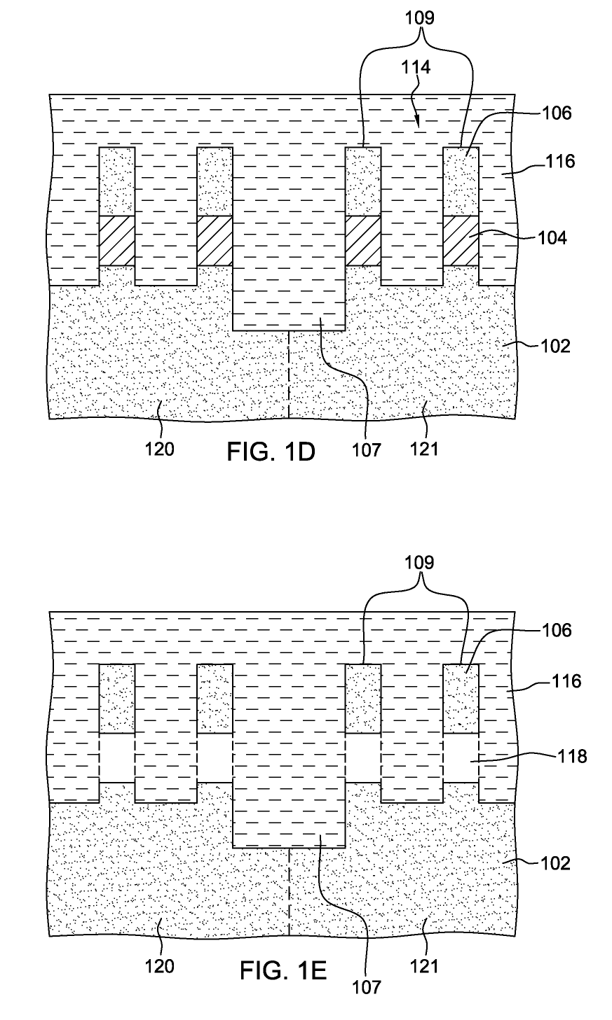

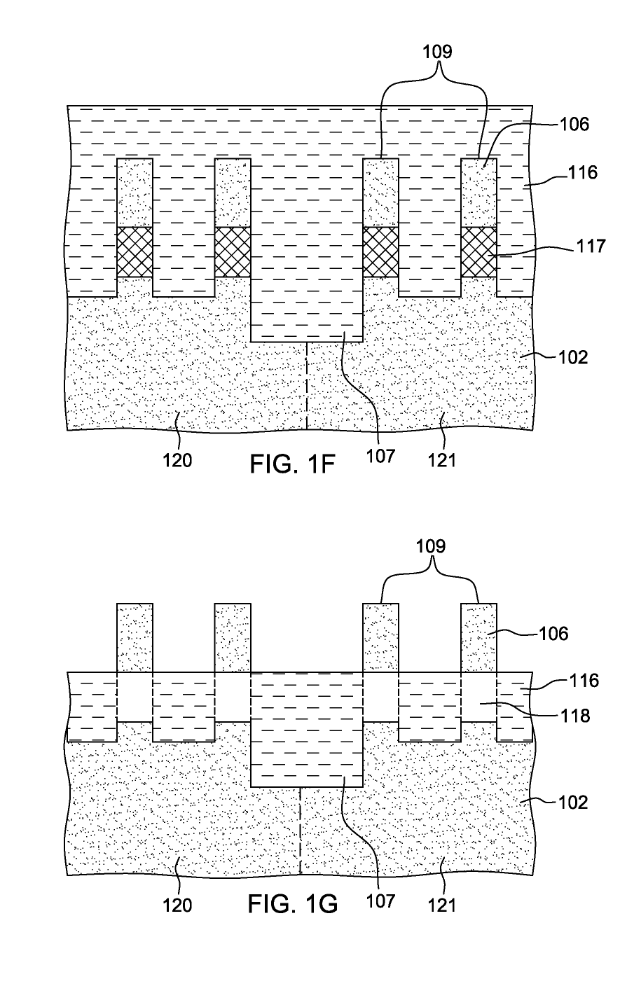

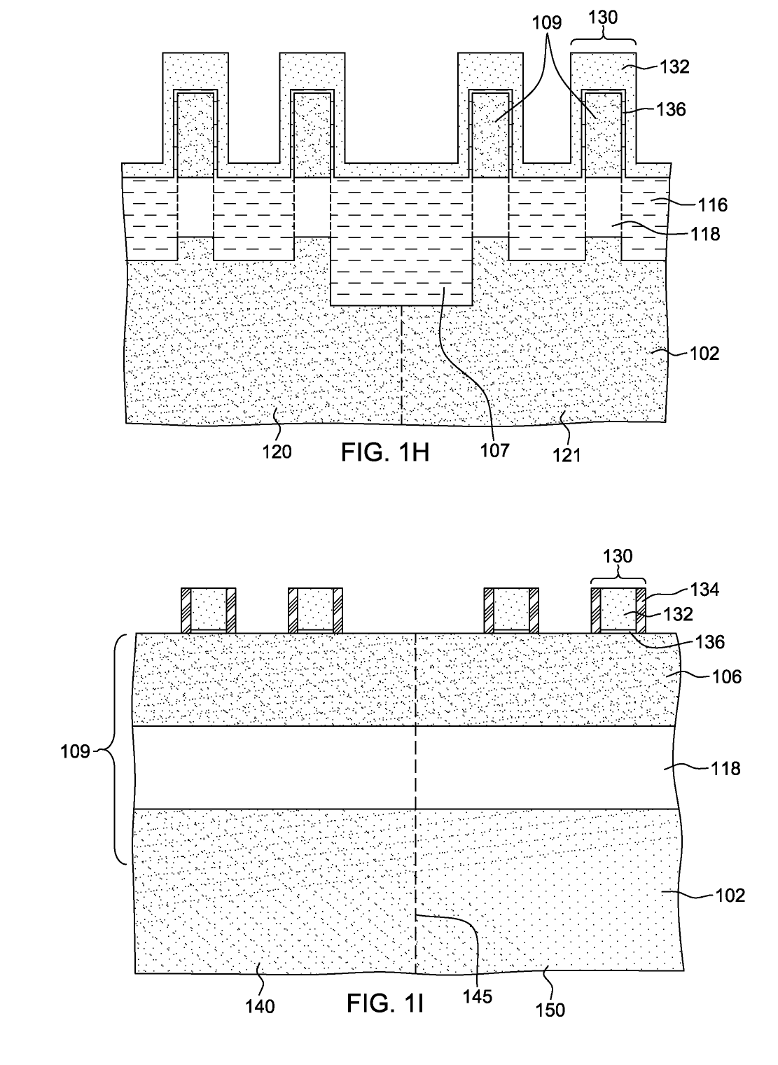

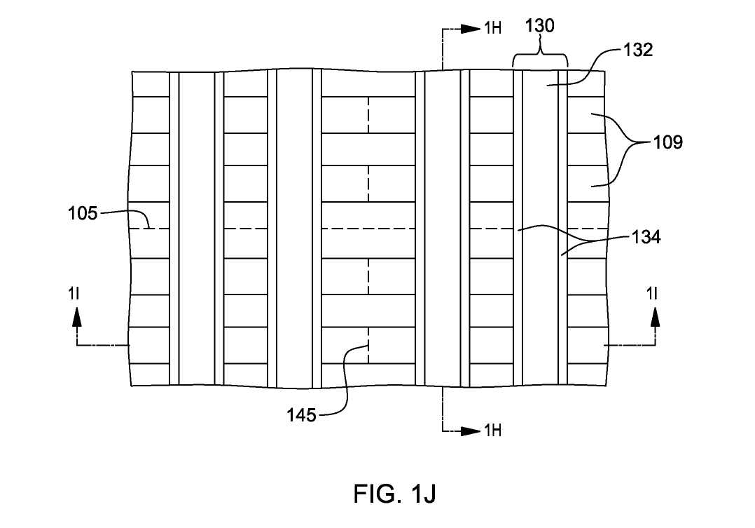

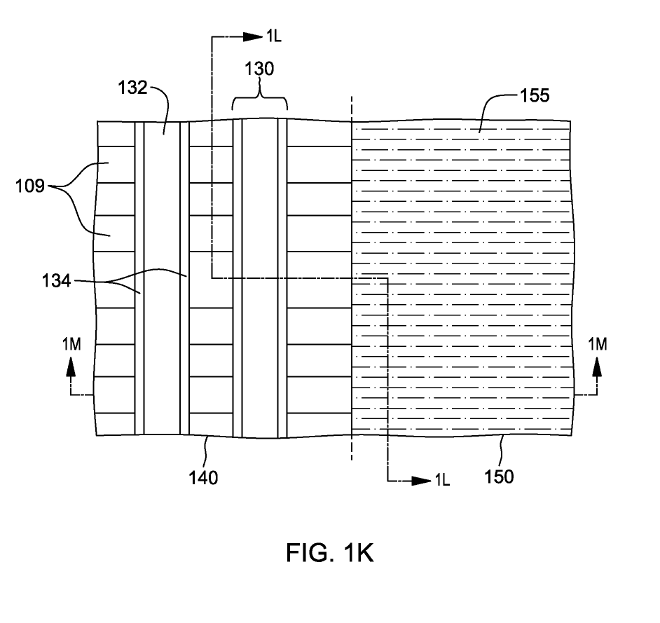

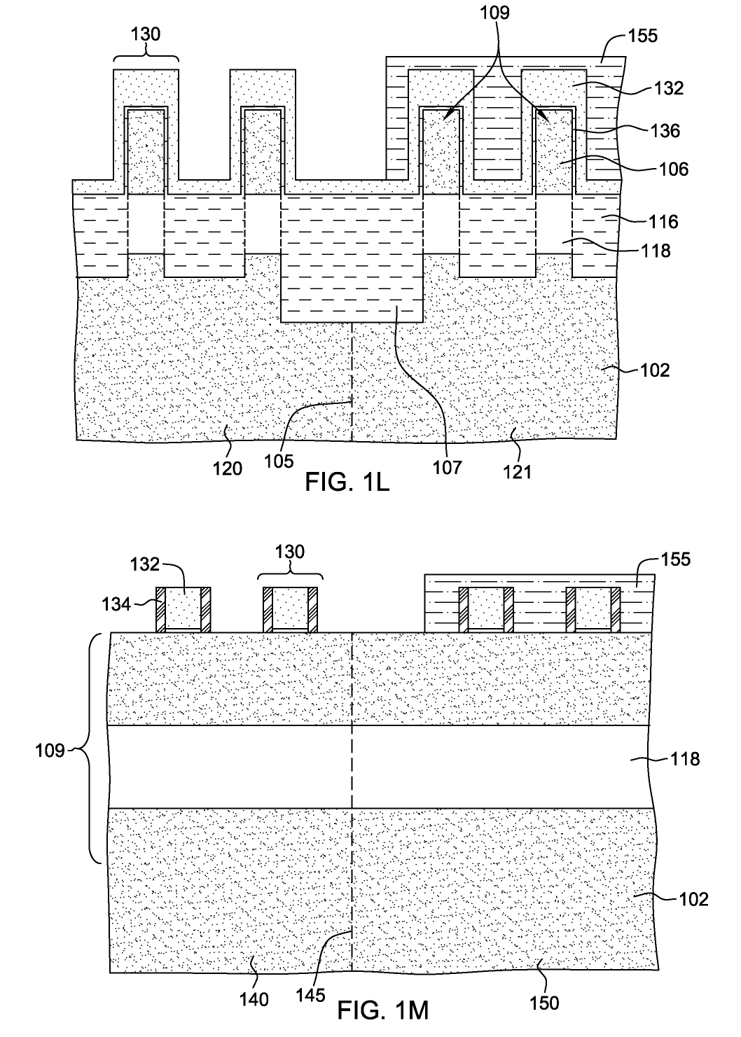

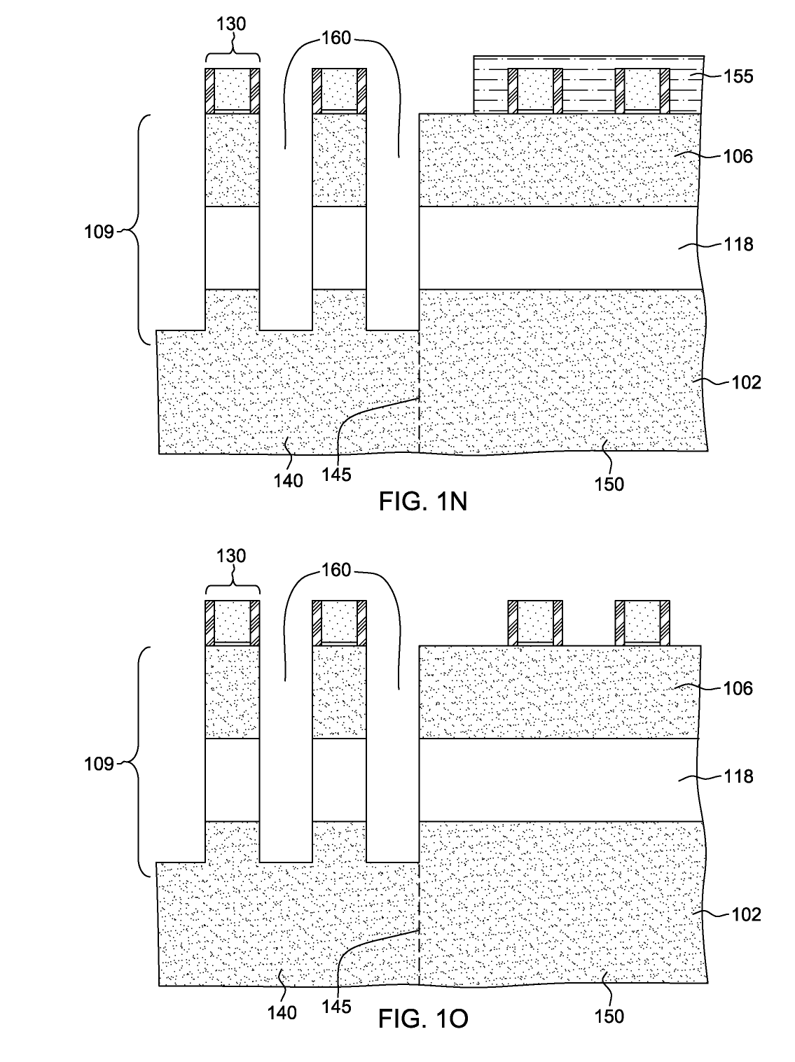

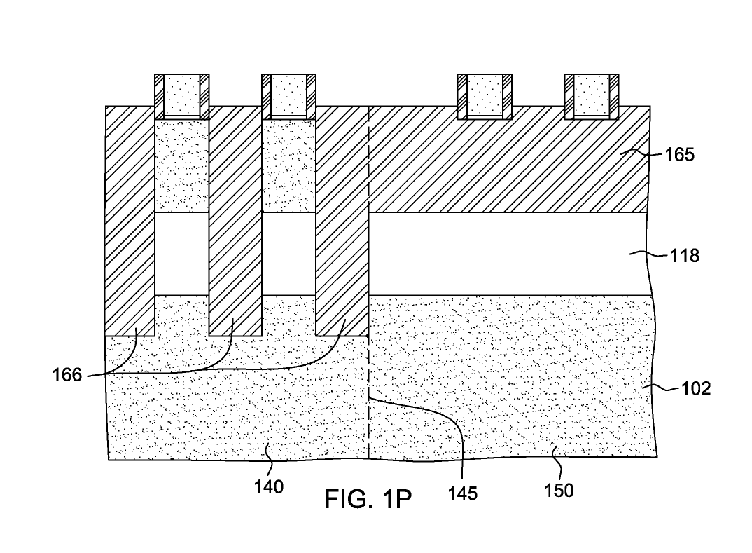

FIG. 1A illustrates one embodiment of an intermediate multi-layer structure, generally denoted 100, obtained during an intermediate stage of fabrication of integrated semiconductor fin devices, in accordance with one or more aspects of the present invention. As illustrated, intermediate multi-layer structure 100 includes a substrate 102, such as a bulk semiconductor material, for example, bulk silicon, and a sacrificial layer 104 formed over substrate 102. In one example, sacrificial layer 104 may be epitaxially grown or deposited over substrate 102, and may be an epitaxial single crystalline semiconductor layer. As another example, sacrificial layer 104 may be a selectively oxidizable material. For example, sacrificial layer 104 may include a layer of silicon germanium, which may be expressed as Siᵢ₋ₓGeₓ wherein x, the atomic ratio of germanium in silicon, may be less than or substantially equal to about 1, although the atomic ratio is about 0.3 to about 0.7 in the present example. As a specific example, the atomic ratio of germanium present in the layer of silicon germanium may be about 0.5. Silicon germanium sacrificial layer 104, may be formed (for example) by various epitaxial growth processes such as ultra-high vacuum chemical vapor deposition (UHV-CVD), low-pressure CVD (LPCVD), reduced-pressure CVD (RPCVD), rapid thermal CVD (RTCVD), or molecular beam epitaxy (MBE). In one example, the CVD-based epitaxial growth may take place at a temperature of between about 600° C. to about 1100° C., while the MBE may typically use a lower temperature. In a specific example, the selective epitaxial growth of the silicon germanium layer may be performed using halogermanes and silanes as the source gases at temperatures below 600° C. A silicon germanium sacrificial layer 104 may have a thickness of between about 1 nanometer and about 100 nanometers, depending on the metastable thickness of the Siᵢ₋ₓGeₓ layer.

FIG. 1B depicts the intermediate structure of FIG. 1A, with an active layer 106 disposed over sacrificial layer 104, creating a multi-layer structure 108. In one example, a selective epitaxial growth process may be used to form active layer 106 over sacrificial layer 104, and a portion of active layer 106 could eventually become a channel area of, for instance, a FinFET in subsequent processing steps. In one example, active layer 106 may be the same material as substrate 102. Epitaxial growth of active layer 106 over sacrificial layer 104 may occur using processes such as CVD or MBE, and the thickness may be about 10 nanometers to about 50 nanometers, by way of example only. In a specific example, the thickness of active layer 106 may be between, for instance, 10 nanometers and 60 nanometers, and active layer 106, such as a layer of silicon, may be grown by flowing over the structure a reactant gas, such as dichlorosilane SiH₂Cl₂, trichlorosilane SiHCl₃, silicontetrachloride SiCl₄ or silane SiH₄ together with a carrier gas such as hydrogen gas to form a uniform silicon active layer 106.

Next, fins 109 of FIG. 1C are formed by removing, for instance, one or more portions of multilayer structure 108, including a portion of active layer 106, a portion of sacrificial layer 104, and a portion of substrate 102. The resulting fins 109 may include a portion of active layer 106, sacrificial layer 104, and substrate 102, as illustrated. By way of example, formation of fins 109 may be achieved through: patterning with various schemes; direct lithography; sidewall image transfer technique; extreme ultraviolet lithography (EUV); an e-beam technique; litho-etch litho-etch; or litho-etch litho-freeze. The removal may be performed, for example, by any suitable etching process, such as an anisotropic dry etching process, for instance, reactive-ion-etching (RIE) in sulfur hexafluoride (SF₆). In one example, pairs of adjacent resulting fins 109 may be separated by openings 114. Although the following numbers are relative and the heights could vary, as one specific example, a fin 109 may have a silicon active layer 106 with a height of about 30 nanometers, a silicon germanium sacrificial layer 104 with a height of about 25 nanometers, and the fin portion of bulk silicon substrate 102 may have a height of about 100 nanometers out of a silicon substrate that might be up to, for instance, approximately 700 micrometers thick. In other examples, the portion of bulk silicon substrate 102 may not be removed, or the portion of sacrificial layer 104 may not be fully removed. The overall height of fin 109 may be, for example, approximately 100 to 200 nanometers, with sacrificial layer 104 being between 10 and 20 nanometers, as one specific example.

Continuing with FIG. 1C, fin cut processing may be employed in a region 105 of the structure to facilitate separation or isolation of the fins into, for instance, a first array 120 and a second array 121, with a width W shown at the fin cut between fins 109 of first array 120 and fins 109 of second array 121 that is larger than the width of openings 114 between adjacent fins within the first or second arrays. In subsequent processing of the intermediate structure, this greater width W could facilitate, for instance, deep STI processing to separate different regions of the wafer, and thus facilitate creation of different fin devices, as described herein. In one example, the first and second groups could be part of the same chip, supporting (for instance) a system-on-chip design.

FIG. 1D, depicts the intermediate structure of FIG. 1C after one or more fins 109 have been surrounded or overlaid with an oxide 116. In one example, oxide 116 may be conformally grown about the at least one fin 109. In another embodiment, oxide 116 may be deposited, for example, using a High Aspect Ratio Process (HARP). In one example, the HARP may include using an O₃/tetraethyl orthosilicate (TEOS) based sub-atmospheric chemical vapor deposition (SACVD) fill process which results in a conformal deposition of silicon oxide. A HARP deposition may be advantageous as a gap-fill deposition within openings with high aspect ratios and may include both a slower deposition rate stage when the slower rate is advantageous for reducing defects, and a higher deposition rate stage when the high rate results in shorter deposition times. In another example, oxide 116 may be a shallow trench isolation (STI) oxide, such as silicon dioxide, or a flowable oxide. By way of example, FIG. 1D also depicts a deep STI region 107 in the area of the fin cut, which would extend parallel with the fins and serve to isolate, in part, resultant fin devices in the fin arrays 120, 121.

FIG. 1E depicts the intermediate structure of FIG. 1D after subjecting fins 109 to a selective oxidation process in the presence of oxide layer 116 to form an isolation layer 118 within fins 109 by selectively oxidizing sacrificial layer 104, while maintaining structural stability of fins 109. The selective oxidation process may be performed, for example, by subjecting oxide 116 to a rapid thermal oxidation (RTO) procedure or by using a steam annealing procedure. It is noted here that performing oxidation or annealing of sacrificial layer 104 in the presence of oxide 116 surrounding fins 109 gives mechanical stability to fins 109 and prevents fins 109 from tilting due to stress caused by the oxidation of the SiGe layer during further processing. In one example, the rapid thermal oxidation may be performed at about 900° C. for about 15 seconds. In another example, steam annealing may be performed in the presence of water vapor at about 500° C. for about 3 hours. As another example, oxide 116 may be conformally grown about fins 109, and annealing of fins 109 could locally oxidize sacrificial layers 104 of fins 109.

It may be the case that annealing the oxidizable material of the sacrificial layer fails to completely oxidize the sacrificial material, for instance, silicon germanium. In that case, as shown in FIG. 1F, germanium 117 may be dispersed in that region of fin 109, which is now an oxide. The dispersed germanium may take the form of, for example, germanium nanocrystals. As one would expect, the more germanium that remains in the fin, the higher the likelihood of reducing the level of electrical isolation of the resultant isolation layer within the fin.

Further processing of the intermediate structure of FIG. 1E may be performed to reveal at least the active layers 106 of fins 109. As depicted in FIG. 1G, oxide 116 is recessed through, for instance, the upper active regions 106 of the fins 109 for further processing as depicted in FIGS. 1H-1P. Any suitable etching process, such as an isotropic dry etching process, for example, a SiCoNi etch process, may be employed to recess, for instance, the HARP oxide. In one specific example, a dry etching process, such as a SiCoNi etching may be employed to remove silicon oxide by using gas mixtures such as, for example, ammonia (NH₃) and nitrogen trifluoride (NF₃) in a plasma processing chamber.

FIG. 1H depicts the intermediate structure of FIG. 1G, after one embodiment of gate structure 130 formation processing. As illustrated, gate structure 130 extends over multiple fins 109, and includes, by way of example, a gate metal 132 and a gate dielectric 136. As one example, a sacrifical gate structure or stack may be disposed across a portion of the electrically isolated top active regions of the fins, with each gate stack including one or more conformally deposited layers such as a gate dielectric layer and one or more work function layers disposed over the gate dielectric layer. Note that the various layers discussed herein may be formed from a variety of different materials using a variety of techniques, such as, for example, atomic layer deposition (ALD) and chemical vapor deposition (CVD). The thickness of the layers may also vary, depending upon a particular application. In other examples, gate structures 130 may be omitted, and other types of devices, such as passive devices (e.g., capacitors, diodes, etc.) which do not include gates, could be created using similar techniques.

As one example, the gate dielectric layer may be formed of a material such as silicon dioxide or a high-k dielectric material with a dielectric constant k greater than about 3.9 (note that k=3.9 for SiO₂), and may be deposited by performing a suitable deposition process, such ALD, CVD, physical vapor deposition (PVD), or the like. Examples of high-k dielectric materials which may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate. As noted, one or more work-function layers may be conformally deposited over the gate dielectric layer, for example, via a deposition process such as ALD, CVD or PVD. The work-function layer(s) may include, for instance, one or more P-type metals or one or more N-type metals, depending on whether the gate structure is part of, for instance, a p-type FET (PFET) or an n-type FET (NFET). The work-function layer(s) may include an appropriate refractory metal nitride, for example, those from Groups IVa-VIa in the Periodic Table, including, for example, titanium nitride (TiN), tantalum nitride (TaN), titanium aluminum nitride (TiAlN), tantalum aluminum nitride (TaAlN), niobium nitride (NbN), vanadium nitride (VN), tungsten nitride (WN), and the like. The gate material, in one example, may include polysilicon or polycrystalline silicon. In another example, the gate material may include a metal, such as, for example, tungsten (W), aluminum (Al), nickel (Ni), cobalt (Co), and titanium (Ti) and may be conformally deposited over the one or more work function layer(s) using processes, such as for instance, ALD or CVD.

FIG. 1I depicts a cross-sectional view of the structure of FIG. 1H, rotated 90° to illustrate the structure along a fin 109. Multiple gate structures 130, with gate metals 132 and sidewall spacers 134 are shown disposed over fin 109, which includes (in one example) active layer 106, isolation layer 118, and a portion of substrate 102. Sidewall spacers 134 may be disposed on the sides of gate metals 132, using conventional deposition processes, such as, for example, CVD or plasma assisted CVD and the spacer material may include, for example, silicon nitride.

Polysilicon (PC) cut 145 processing may be employed to separate or isolate one or more fins into one or more fin regions transverse to the parallel-extending fins 109. In the depicted example, the PC cut 145 divides the illustrated fin 109 into a first fin region 140 and a second fin region 150 by, for example, providing a dielectric isolation barrier (not shown) extending vertically into the one or more fins at the PC cut 145 to, at least, intersect with the isolation layer 118 therein, and in certain embodiments, to pass therethrough into substrate 102. As one example, this dielectric isolation barrier may be an oxide barrier extending vertically through fin 109.

FIG. 1J depicts a plan view of the intermediate structure of FIGS. 1H & 1I, and illustrates multiple fins 109 parallel to one another, and multiple gate structures 130 provided over fins 109. Gate structures 130, which may have gate metal 132 and sidewall spacers 134, as noted, overlap fins 109 in areas to constitute, for instance, the gates of multiple FinFETs. The length of fins 109 may be a micron, several micrometers, or even the diameter of the wafer. By way of example, the transverse nature of the fin cut 107 and the PC cut 145 is also depicted. Line 1H-1H indicates the orientation of the view depicted in FIG. 1H, while line 1I-1I indicates the orientation of the view depicted in FIG. 1I.

FIG. 1K depicts the intermediate structure of FIG. 1J after further processing, wherein first fin region 140 and second region fin 150 of the structure are denoted. In one example, a protective layer 155 such as a protective mask is provided over second fin region 150, thereby protecting the structures of second fin region 150 from processing to be performed within first fin region 140. In one example, protective layer 155 may include a material such as, for example, silicon nitride and may be deposited using conventional deposition processes, such as, for example, CVD or plasma-enhanced CVD (PECVD). In one specific example, silicon nitride may be deposited using process gases such as, for example, dichlorosilane (SiH₂Cl₂) and ammonia (NH₃) and using known process conditions. In another example, where no high temperature processes are involved, ODL and FCVD masking may also be used. In a further example, a low-pressure CVD or ALD-created mask may be used.

Protective layer 155 is, for instance, a hard mask layer conformally deposited over the structures, including the gate material, within the second region of the wafer and may include a nitride or an oxide, such as, for example, silicon nitride or silicon oxide, or an oxynitride or a combination thereof. The deposition processes may include any conventional process such as, for example, low temperature CVD, PECVD, or ALD. In another example, other hard mask materials, such as metal oxides or metals, may be used. Note, however, that if the mask is required for selective epi deposition, metals or metal oxides should not be used, as they are not entertained in the epi chamber.

FIG. 1L depicts the intermediate structure of FIG. 1K, taken along line 1L-1L thereof. As illustrated, multiple fins 109 are surrounded by protective layer 155 within the fin second region 150 of fins 109 in order to protect the fins in this region from processing to occur in the exposed, first fin region 140 of the fins. This is further illustrated in the cross-sectional depiction of FIG. 1M, which is taken along line 1M-1M in FIG. 1K.

FIG. 1N depicts the intermediate structure of FIG. 1M after processing to form fin recesses 160 within fins 109 in first fin region 140, while fins in second fin region 150 remain protected. In one example, fin recesses 160 extend through isolation layer 118 into substrate 102. As illustrated, fin recesses 160 may be disposed adjacent to gate structures 130 within first region 140, and may be formed using any suitable etching process, such as isotropic dry or wet etching processing. In one example, isotropic dry etching may be used by, for example, ion beam etching, plasma etching or isotropic RIE. In another example, isotropic wet etching may also be performed using etching solutions such as, for example, HF:Nitric:Acetic acid solution (also known as HNA etch). As another example, the fin recesses could be formed on different fins, with a protective mask protecting portions of multiple fins.

In FIG. 1O, the intermediate structure of FIG. 1N is depicted with protective layer 155 having been removed subsequent to the modification of fin 109 in first fin region 140 to create fin recesses 160. In another example, the protective layer may not be immediately removed before subsequent processing, allowing for processing of the first region to continue, while the second region remains protected.

FIG. 1P depicts proceeding with formation of different fin devices, and is a split view of the intermediate structure of FIG. 1O with material 165 having been provided. In particular, first fin region 140 is viewed in cross section through a fin 109, and second fin region 150 is viewed in cross section between adjacent fins 109. In the illustrated example, material 165 extends down to substrate 102 in first fin region 140, and for instance, at least partially overlies fins 109 in second fin region 150. From this structure, first architectural type fin devices may be created in first fin region 140, having embedded stress elements, and second architectural type fin devices may be created in second fin region 150, wherein the first architectural type and second architectural type devices are different. In one example, the first architectural type fin devices include embedded source or drain elements 166 which extend, in this example, through isolation layer 118 into substrate 102, second architectural type fin devices may be isolated-type fin transistors, where the active layer of the fin in second fin region 150 remains separated or isolated from substrate 102 by isolation layer 118. Note that in using the isolated fins disclosed herein, the different architecture type devices may incorporate different isolation schemes, such as junction-isolated, partially isolated, or fully isolated.

In one example, the structure of FIG. 1P may be obtained by epitaxially growing a semiconductor material, at least partially, from substrate 102 through fin recesses 160 in first fin region 140 to, for instance, at least partially extend over fins 109 in second fin region 150. As previously noted, the split view of FIG. 1P depicts both grown material 165 from substrate 102 in first fin region 140, and material 165 extending over fin 109 in second fin region 150. The semiconductor material grown may be, for example silicon germanium or silicon carbon. Silicon germanium could be grown in order to fabricate a p-type MOS (PMOS) structure, while silicon carbon could be grown in order to fabricate an n-type MOS (NMOS) structure. In another example, there could be multiple steps of epitaxial growth, first growing silicon germanium, followed by growing silicon carbon, with the result being one each of a PMOS and NMOS transistor, yielding a CMOS circuit. Epitaxially growing the semiconductor material would, in one embodiment, take place starting with the substrate, because the semiconductor substrate is (in one example) a crystal material from which epitaxial growth is possible, but in another example epitaxial growth could take place from, for instance, a portion of the side walls of fins 109, such as active layer 106.

Stress-inducing materials, such as one or more tensile stress inducing materials to improve the tensile stress of NMOS transistor or one or more compressive stress inducing materials to improve the compressive stress of a PMOS transistor, may also be epitaxially grown. In one example, the tensile stress of an NMOS transistor may be improved using tensile stress inducing materials, such as silicon doped with carbon and phosphorous Si:C(P), where the atomic percentage of carbon may be about 1 percent to about 3 percent or silicon doped with phosphorus (SiP), where the atomic percentage of phosphorus may vary, for instance, between about 0.1 percent to about 10 percent. The term “tensile stress inducing material” denotes a material layer having an intrinsic tensile stress, in which the intrinsic tensile stress produces a tensile stress in one or more adjacent materials. For instance, a tensile stress-inducing material may be a material having an intrinsic compressive stress, in which the intrinsic compressive stress produces a tensile stress in one or more adjacent materials, or a material with a larger lattice constant and volume than the adjacent material that is lattice-matched to the stress-inducing material. The tensile stress inducing materials are epitaxially grown using selective epitaxial growth via various methods, such as, for example, CVD, RPCVD, LPCVD, or other applicable methods. The selective epitaxial growth starts when at least one semiconductor source gas is injected into the reaction chamber. In one example, silicon doped with phosphorus may be formed using gases such as, for example, dichlorosilane (SiH₂Cl₂) gas or silane (SiH₄) with phosphine (PH₃). In another example, the semiconductor source gas may be a silicon source gas, such as, for example, silane (SiH₄) gas, a disilane (Si₂H₆) gas, a dichlorosilane (SiH₂Cl₂) gas, a SiHCl₃ gas and a SiCl₄ gas or may include a carbon source gas for the growth of SiC.

In another example, the compressive stress of a PMOS may be improved using compressive stress inducing materials for the raised source and drain, such as, for example, silicon germanium (SiGe) where the atomic percentage of germanium may vary, for instance, between about 0.1 percent to about 10 percent, and may be epitaxially grown above the silicon (Si) fins. The term “compressive stress inducing material” denotes a material having an intrinsic compressive stress, in which the intrinsic compressive stress produces compressive stress in one or more adjacent materials. For instance, a compressive stress-inducing material may be a material having an intrinsic tensile stress, in which the intrinsic tensile stress produces a compressive stress in one or more adjacent materials, or a material with a smaller lattice constant and larger volume than the adjacent material that is lattice-matched to the stress-inducing material. The epitaxial growth may be realized using selective epitaxial growth via various methods, such as, for example, CVD, RPCVD or other applicable methods and may be initiated using a silicon germanium source gas, which may include a stoichiometric ratio of silicon source gas and the germanium source gas. The stoichiometric ratio depends on the percentage of SiGe that is being grown. In addition, the SiGe may be doped as well. The semiconductor source gas may instead be, for example, one of the more advanced gases from the family of germyl-silanes, such as H₃GeSiH₃, (H₃Ge)₂SiH₂, (H₃Ge)₃SiH, or (H₃Ge)₄Si.

With reference to FIG. 1P, those skilled in the art should note that additional processing could take place to, for example, provide additional or different devices (such as passive devices), depending on the particular circuit architecture design. By way of further example, the epitaxially grown semiconductor material could wrap around more than one fin creating a multi-channel device. In another example, the fin recesses may be formed in different fins of the wafer, and the material deposited in the multiple fin recesses in the different fins.

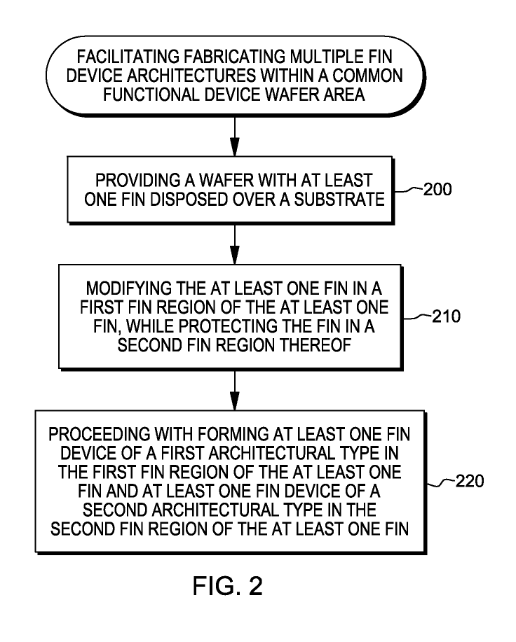

By way of summary, FIG. 2 depicts one embodiment of a process for facilitating fabricating multiple fin device architectures, for instance, within a common functional device wafer area 200, in accordance with one or more aspects of the present invention. In the embodiment depicted, the method includes providing a wafer with at least one fin disposed over a substrate, and including a isolation layer 210; modifying the at least one fin in a first fin region of the at least one fin, while protecting the fin in a second fin region thereof 220; and proceeding with forming at least one fin device of a first architectural type in the first fin region of the at least one fin and at least one fin device of a second architectural type in the second fin region of the at least one fin, wherein the first architectural type and the second architectural type are different fin device architectures 230.

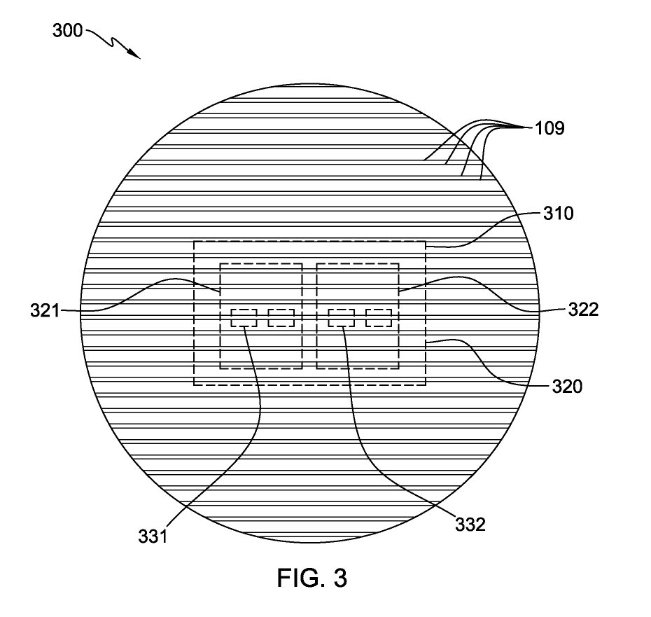

FIG. 3 is a schematic representation of a wafer 300 having a common functional device wafer area 310, with a first fin region 312 thereof containing a fin device of a first architectural type, and a second fin region 314 containing a fin device of second architectural type.

As illustrated in FIG. 3, wafer 300 includes a plurality of fins 109, some of which extend through first fin region 321, which contains, for example, fin devices 331 of a first architectural type, and second region 322, which contains fin device 332 of a second architectural type. In another example, the fin devices 331 of the first architectural type and the fin devices of the second architectural type may be located on different fins of the plurality of fins 109. In a further example, the fin devices of the first architectural type and the fin devices of the second architectural type could be located in different functional device areas of the wafer.

Note that, in one implementation, the at least one fin device of the second architectural type is a fully-isolated fin device. For instance, the at least one fin device of the second architectural type may be an isolated-type fin transistor where the source, drain and channel regions are isolated, that is, are disposed above the at least one dielectric isolation layer within the at least one fin.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method comprising:
facilitating fabricating multiple fin device architectures, the facilitating fabricating comprising:
providing a wafer with at least one fin disposed over a substrate, the at least one fin including an isolation layer;
modifying the at least one fin in a first fin region, while protecting the at least one fin in a second fin region thereof; and
proceeding with forming at least one fin device of a first architectural type in the first fin region and at least one fin device of a second architectural type in the second fin region, wherein the first architectural type and the second architectural type comprise different fin device architectures.

2. The method of claim 1, wherein the at least one fin device of the first architectural type comprises at least one fin transistor of the first architectural type.

3. The method of claim 2, wherein the at least one fin device of the second architectural type comprises at least one fin transistor of the second architectural type.

4. The method of claim 3, wherein the modifying the first fin region of the at least one fin comprises forming at least one fin recess in one fin of the at least one fin within the first fin region while protecting the one fin in the second fin region of the at least one fin.

5. The method of claim 4, wherein the at least one fin recess extends through the isolation layer to the substrate beneath the one fin.

6. The method of claim 5, wherein the wafer comprises multiple gate structures disposed over the one fin, and wherein the modifying comprises forming multiple fin recesses in the one fin in the first fin region of the at least one fin, each fin recess being disposed adjacent to one or more gate structures of the multiple gate structures in the first fin region of the at least one fin.

7. The method of claim 5, wherein the substrate comprises a semiconductor substrate, and the proceeding comprises epitaxially growing a semiconductor material from, at least in part, the semiconductor substrate through the at least one fin recess in the one fin, the epitaxially growing further providing the semiconductor material, at least partially, over the one fin in the second fin region.

8. The method of claim 7, wherein the epitaxially-grown semiconductor material comprises one of silicon germanium or silicon carbon.

9. The method of claim 3, wherein the at least one fin transistor of the first architectural type in the first fin region comprises at least one embedded stress element extending through the isolation layer into the substrate, and the at the least one fin transistor of the second architectural type in the second fin region lacks any embedded stress element extending into the substrate.

10. The method of claim 9, wherein the at least one transistor of the second architectural type in the second fin region comprises an isolated-type fin transistor.

11. The method of claim 1, wherein providing the wafer comprises:
providing a multi-layer structure, the multi-layer structure comprising:
the substrate;
the isolation layer disposed over the substrate; and
an active semiconductor layer disposed over the isolation layer; and
removing at least a portion of the multi-layer structure to create the at least one fin, the at least one fin comprising a region of the active layer disposed above a region of the isolation layer.

12. The method of claim 11, wherein the substrate comprises a semiconductor substrate and providing the multi-layer structure comprises:
providing an intermediate semiconductor structure, comprising:
the semiconductor substrate;
a sacrificial layer over the substrate, the sacrificial layer comprising an oxidizable material; and
the active semiconductor layer disposed over the sacrificial layer;
etching the intermediate semiconductor structure to create the at least one fin, each fin of the at least one fin comprising a portion of the active layer, a portion of the sacrificial layer and a portion of the semiconductor substrate; and
selectively oxidizing the sacrificial layer of the at least one fin, while maintaining structural stability therefore, wherein the oxidized sacrificial layer provides the isolation layer.

13. The method of claim 12, wherein providing the intermediate semiconductor structure comprises epitaxially growing the sacrificial layer.

14. The method of claim 13, wherein the selectively oxidizing comprises:
providing a conformal oxide about the at least one fin; and
annealing the at least one fin and conformal oxide to locally oxidize the sacrificial layer therein.

15. The method of claim 11, wherein the at least one fin device of the first architectural type comprises at least one fin transistor of the first architectural type, and wherein the at least one fin device of the second architectural type comprises at least one fin transistor of the second architectural type.

16. The method of claim 15, wherein the at least one fin transistor of the first architectural type in the first fin region comprises at least one embedded stress element extending through the isolation layer into the substrate, and the at least one transistor of the second architectural type in the second fin region comprises an isolated-type fin transistor.

17. The method of claim 1, wherein protecting the second fin region comprises:
providing a protective mask over the second fin region of the at least one fin before modifying the at least one fin in the first fin region thereof and
removing the protective mask over the second fin region subsequent to modifying the at least one fin in the first fin region thereof.

18. A semiconductor structure comprising:
a semiconductor substrate;
at least one fin residing over the semiconductor substrate and comprising an active layer, and an isolation layer between the active layer and the semiconductor substrate; and
at least one fin device of a first architectural type in a first fin region of the at least one fin and at least one fin device of a second architectural type in a second fin region of the at least one fin, wherein the first architectural type and the second architectural type comprise different fin device architectures.

19. The semiconductor structure of claim 18, wherein the at least one fin device of the first architectural type comprises at least one fin transistor of the first architectural type, and wherein the at least one fin transistor of the first architectural type in the first fin region of the at least one fin comprises at least one embedded stress element extending through the isolation layer of the at least one fin into the semiconductor substrate.

20. The semiconductor structure of claim 19, wherein the at least one fin device of the second architectural type comprises at least one fin transistor of the second architectural type, the at least one fin transistor of the second architectural type comprising an isolated-type fin transistor.

21. The semiconductor structure of claim 18, wherein the first architectural type and the second architectural type comprise different fin device isolation architectures relative to the isolation layer of the at least one fin.
